(19) United States
(12) Patent Application Publication
(10) Pub. No.: US 2026/0361281 A1
(43) Pub. Date: Nov. 12, 2026

(54) TRULY SYMMETRIC STRUCTURES AND CIRCUITS USING STACKED WAFERS

(71) Applicant: GlobalFoundries U.S. Inc., Malta, NY (US)

(72) Inventors: Venkata Narayana Rao Vanukuru, Bengaluru (IN); Binoy Kumar Paul, Bengaluru (IN)

(21) Appl. No.: 19/199,516

(22) Filed: May 6, 2025

(51) Int. Cl. H03F 3/45; H10D 88/00

(52) U.S. Cl. CPC H03F 3/45179; H10D 88/00

(57) ABSTRACT

Circuits and associated structures fabricated in stacked wafers having true symmetry. A structure includes: a plurality of devices and components fabricated in a wafer stack having a first wafer and a second wafer, wherein a first set of devices is implemented in the first wafer and a second set of devices is implemented in the second wafer, and wherein the devices and components have side-by-side symmetry from a through wafer stack projection about a center line.

### BACKGROUND

The present disclosure relates semiconductor structures and circuits, more particularly, to structures and circuits implemented with stacked wafers that provide structural symmetry.

Certain circuits, such as differential amplifiers, require differential operations. A differential amplifier is an electronic circuit that amplifies the difference between two input voltages, while rejecting any voltage that is common to both inputs. Unlike traditional amplifiers with a single input, differential amplifiers have two input terminals, and the output signal is proportional to the difference between the two input voltages. Higher performance of a differential amplifier can be achieved when the amplifier is implemented with structural symmetry, which will minimize the common mode signal and boost performance.

### SUMMARY

Disclosed herein are embodiments of circuits and structures implemented on stacked wafers that have true structural symmetry.

Illustrative aspects include a structure having a plurality semiconductor devices and components fabricated in a wafer stack, wherein a first set of devices is implemented in a first wafer and a second set of devices is implemented in a second wafer, and wherein the devices and components have side-by-side symmetry from a through wafer stack projection about a center line.

Other illustrative aspects include a circuit having a plurality of subcircuits, wherein each subcircuit is implemented with a structure that includes: a plurality of devices and components fabricated in stacked wafers, wherein a first set of devices is implemented in a first wafer and a second set of devices is implemented in a second wafer, and wherein the devices and components have side-by-side symmetry from a through wafer stack projection relative to a center line.

In some aspects, the circuit includes a differential amplifier.

Other illustrative aspects include a structure, comprising: a plurality of metal oxide semiconductor field effect transistors (MOSFET) devices and components fabricated in a wafer stack, wherein a first set of devices is implemented in a first wafer and a second set of devices is implemented in a second wafer, and wherein the devices and components have side-by-side symmetry from a through wafer stack projection about a center line.

Further aspects include a structure, comprising: a plurality of capacitors and components fabricated in a wafer stack, wherein a first set of capacitors is implemented in a first wafer and a second set of capacitors is implemented in a second wafer, and wherein the capacitors and components have side-by-side symmetry from a through wafer stack projection about a center line.

In other aspects, the structure can include one of a transformer or a balun.

Two or more aspects described in this disclosure, including those described in this summary section, may be combined to form implementations not specifically described herein.

The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1 is a schematic circuit diagram illustrating a differential amplifier, according to embodiments;

FIG. 2A depicts a generic stacked wafer structure, according to embodiments;

FIG. 2B depicts a view of the stacked wafer structure of FIG. 2A showing structural symmetry, according to embodiments;

FIG. 3A depicts a circuit diagram having active devices, according to embodiments;

FIG. 3B depicts an associated stacked wafer structure of the circuit of FIG. 3A, according to embodiments;

FIG. 3C depicts an exploded view of a first wafer component and associated circuit diagram of the structure of FIG. 3B, according to embodiments;

FIG. 3D depicts an exploded view of a second wafer component and associated circuit diagram of the structure of FIG. 3B, according to embodiments;

FIG. 4A depicts a circuit diagram of a transformer, according to embodiments;

FIG. 4B depicts an associated stacked wafer structure of the circuit of FIG. 4A, according to embodiments;

FIG. 4C depicts an exploded view of a first wafer component and associated circuit diagram of the structure of FIG. 4B, according to embodiments;

FIG. 4D depicts an exploded view of a second wafer component and associated circuit diagram of the structure of FIG. 4B, according to embodiments;

FIG. 5A depicts a circuit diagram of a capacitor circuit, according to embodiments;

FIG. 5B depicts an associated stacked wafer structure of the circuit of FIG. 5A, according to embodiments;

FIG. 5C depicts an exploded view of a first wafer component and associated circuit diagram of the structure of FIG. 5B, according to embodiments; and

FIG. 5D depicts an exploded view of a second wafer component and associated circuit diagram of the structure of FIG. 5B, according to embodiments.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

As noted above, the ability to implement symmetrical circuits for differential amplifiers and the like is critical for performance. Implementing such circuits on stacked wafers has the potential to greatly reduce the footprint of the structure. Stacked wafers, which are regularly used to implement active and passive devices, are fabricated with a three-dimensional integration process where multiple semiconductor wafers are vertically stacked and interconnected to create a single, more complex integrated circuit (IC) or package. However, achieving structural symmetry in circuits is a challenge when stacked wafers are used. The present disclosure provides circuits and structures that can be implemented on stacked wafers, while providing true structural symmetry.

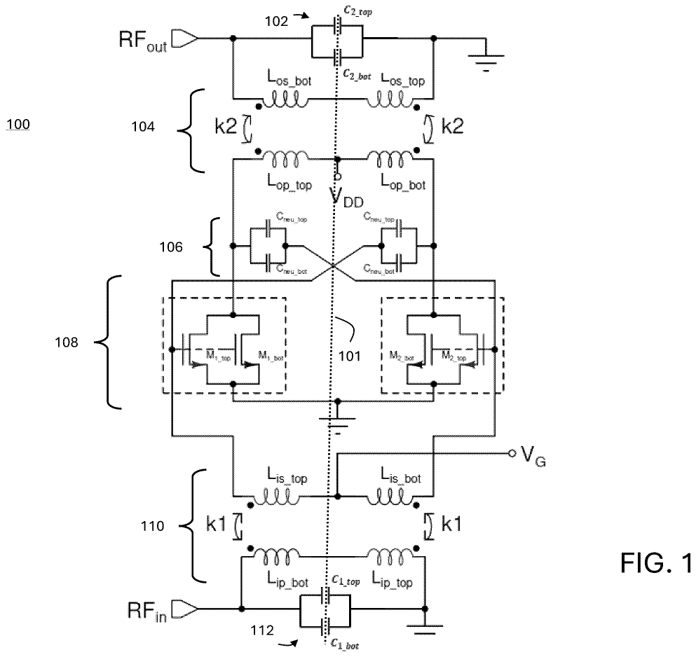

FIG. 1 depicts a differential amplifier circuit 100 having a symmetrical layout, i.e., the left and right components are a mirror image of each other about center line 101. Circuit 100 includes various subcircuits that each have a set of devices and are themselves symmetrical when implemented in stacked wafers. As shown, circuit 100 includes a first capacitor subcircuit 102, a first transformer subcircuit 104, a vertical natural capacitor (VNCAP) or a metal-insulator-metal capacitor (MIMCAP) subcircuit 106, a metal-oxide semiconductor field-effect transistor (MOSFET) subcircuit 108, a second transformer subcircuit 110, and a second capacitor subcircuit 112. As described in more detail herein, each subcircuit includes one or more devices in a first (e.g., bottom) wafer and one or more devices in a second (e.g., top wafer) that are structurally symmetrical about center line 101. Additionally, each subcircuit includes components such as interconnects that couple devices within the subcircuit. By implementing each of these in stacked wafers with symmetrical structures, a truly symmetrical circuit is achieved.

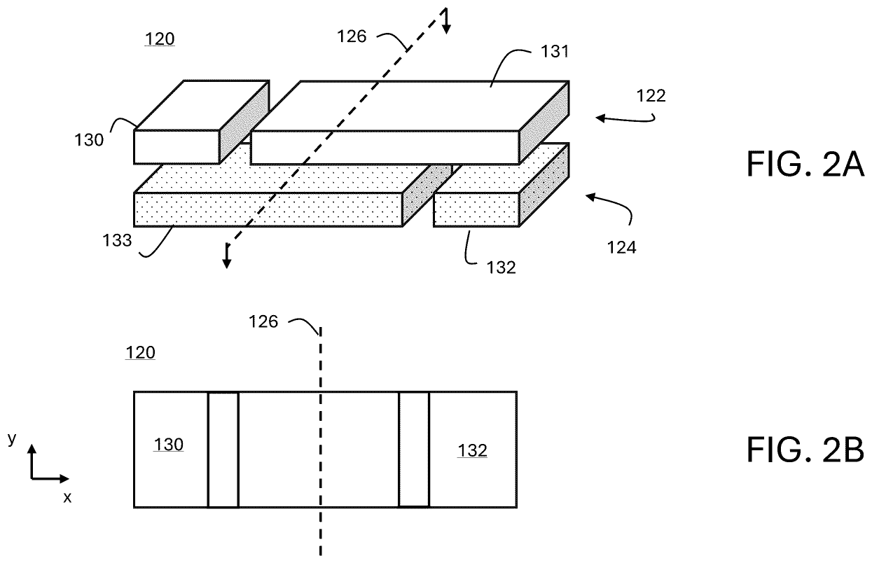

FIG. 2A depicts a perspective view of a generalized stacked wafer structure 120 implemented in a top wafer 122 and a bottom wafer 124. In this example, structure 120 includes two semiconductor devices (“devices”) 130 and 132, which may for example comprise active devices such as MOSFETs, and/or passive devices such as capacitors, transformers, inductors, etc. Structure 120 further includes associated components 131, 133 such as structural components and electrical connections, e.g., wiring, vias, etc. FIG. 2B depicts a “through wafer stack projection” of structure 120, i.e., the projection shows all of the devices and components collapsed in a two-dimensional x-y view, i.e., collapsed along the z-axis. As can be seen in FIG. 2A, the top wafer 122 is implemented differently than the bottom wafer 124. However, from a through wafer stack projection, structure 120, formed from devices and components 130, 131, 132, 133, has true side-by-side structural symmetry relative to center line 126. Devices 130, 132 and components 131, 133 are accordingly implemented in different wafers with different structures, yet maintain the side-by-side symmetry. It is further noted that the wafers 122, 124 can have dissimilar materials and properties, including different dielectric properties. For example, one of the wafers may be fabricated with a high-k dielectric and the other wafer may be fabricated with a low-k dielectric, a normal dielectric, or a magnetic material. Illustrative high-k dielectrics include, e.g., hafnium silicate, zirconium silicate, hafnium dioxide and zirconium dioxide. Illustrative low-k dielectrics include, e.g., fluorine-doped silicon dioxide, carbon-doped oxide, and porous silicon dioxide. Normal dielectrics may for example include silicon dioxide and silicon nitride. Magnetic wafers may for example include ferrite.

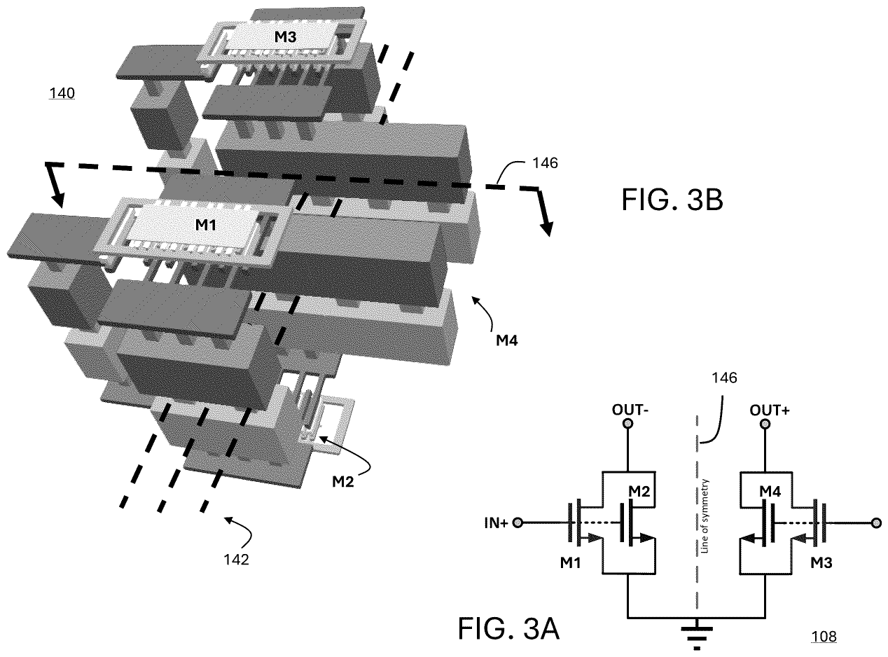

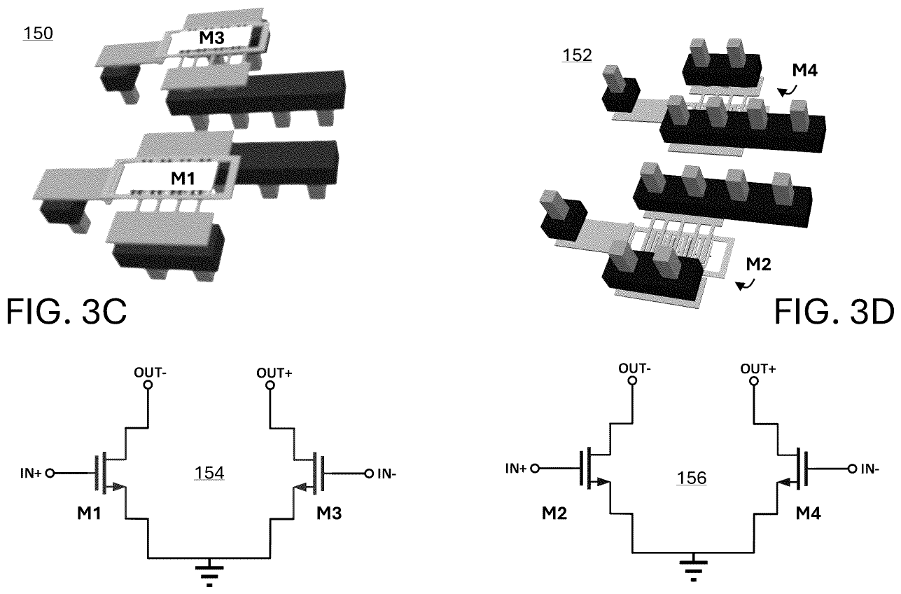

FIGS. 3A-3D describe an illustrative embodiment of the MOSFET subcircuit 108 and associated structure shown in FIG. 1. FIG. 3A depicts the MOSFET subcircuit 108 shown in FIG. 1 and FIG. 3B depicts a perspective view of an associated three-dimensional structure 140 for implementing the MOSFET subcircuit 108. Structure 140 is implemented in two wafers, above and below dashed lines 142. As shown in both FIGS. 3A and 3B, the subcircuit and structure 108, 140 include four MOSFETS, M1, M2, M3 and M4. MOSFETS M1 and M3 are implemented in the top wafer, and M2 and M4 are implemented in the bottom wafer. Both the subcircuit 108 and associated structure 140 have true side-by-side symmetry about center line 146, i.e., from a through wafer stack projection (not shown). Of the four MOSFET devices, a first subset or pair M1 and M2 (and associated components) are formed on a first side of center line 146 and a second subset or pair M3, M4 (and associated components) are formed on a second side of the center line 146. FIGS. 3C and 3D show exploded views of the top and bottom wafer sections 150, 152 of structure 140 and associated circuit components 154, 156. Note that top MOSFETS (M1, M3) and bottom MOSFETS (M2, M4) can be fabricated differently (e.g., using a thin/thick oxide, air gap/non air gap, distance from the substrate, etc.).

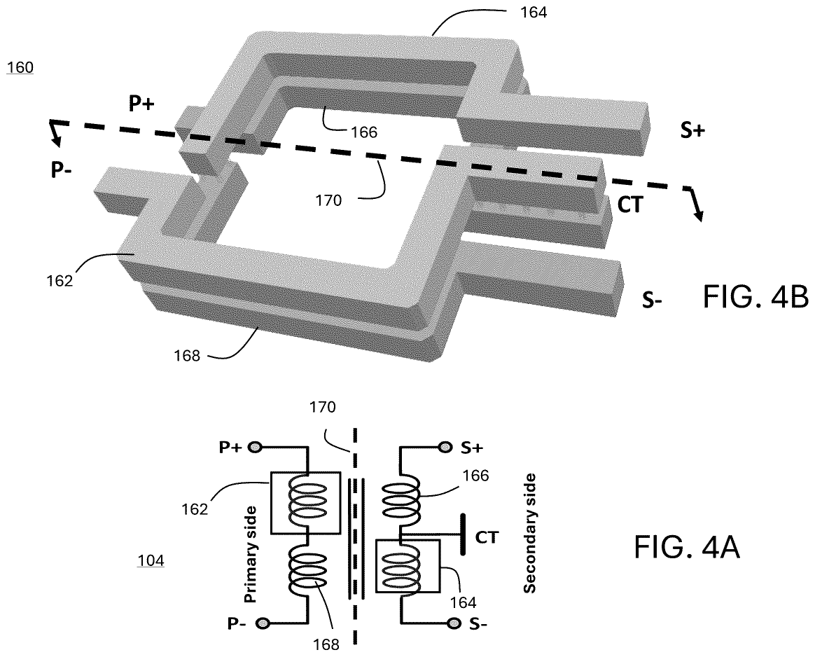

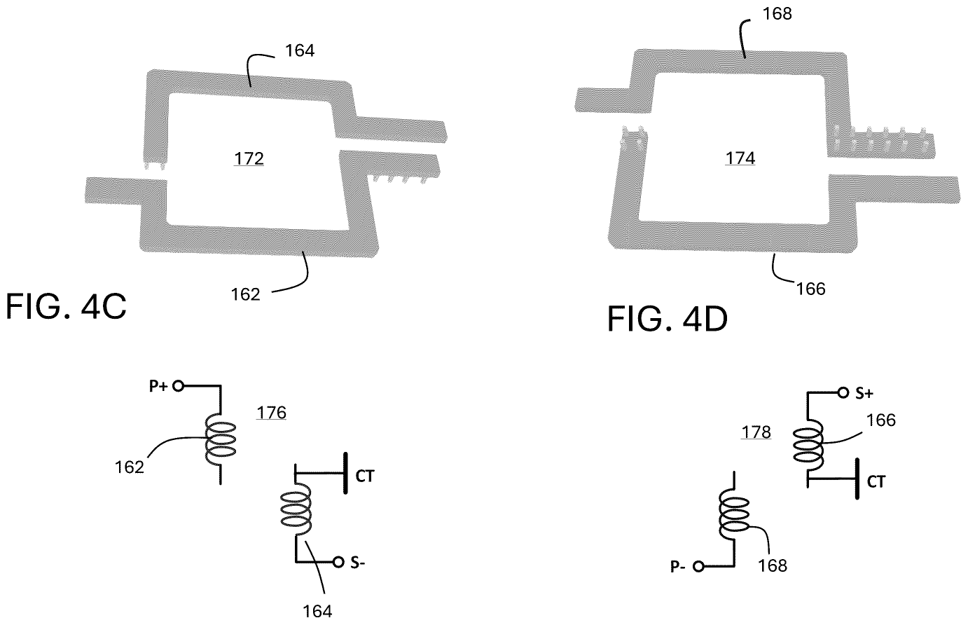

FIGS. 4A-4D describe an illustrative embodiment of the transformer subcircuit 104 shown in FIG. 1. FIG. 4A depicts the transformer subcircuit 104 and FIG. 4B depicts a perspective view of an associated three-dimensional structure 160 for implementing the transformer subcircuit 104. Structure 160 is implemented in two wafers, with inductor devices 162, 164 being implemented in the top wafer and inductor devices 166, 168 being implemented in the bottom wafer. From a top-down perspective (i.e., through wafer stack projection), structure 160 is left-right symmetrical about center line 170. A first subset or pair of the inductors 162, 168 are formed on a first side of the center line and a second subset or pair of the inductors 164, 166 are formed on a second side of the center line 170.

FIGS. 4C and 4D show exploded views of the top and bottom wafer sections 172, 174 of structure 160 and associated circuit components 176, 178. Accordingly, with a half turn in the top wafer and a half turn in the bottom wafer, a truly symmetric 1:1 transformer is achieved. Note that the thickness and conductivity of the top wafer and bottom wafer can be different.

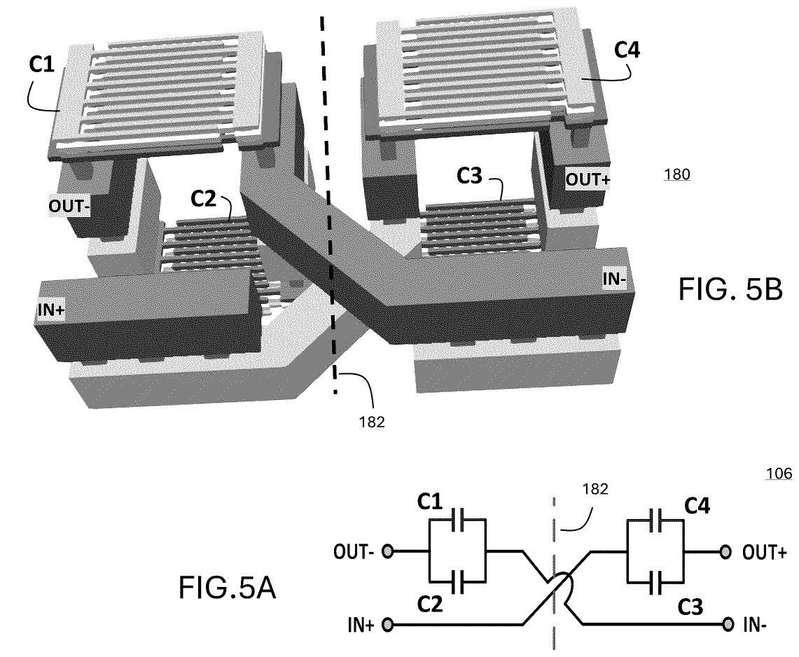

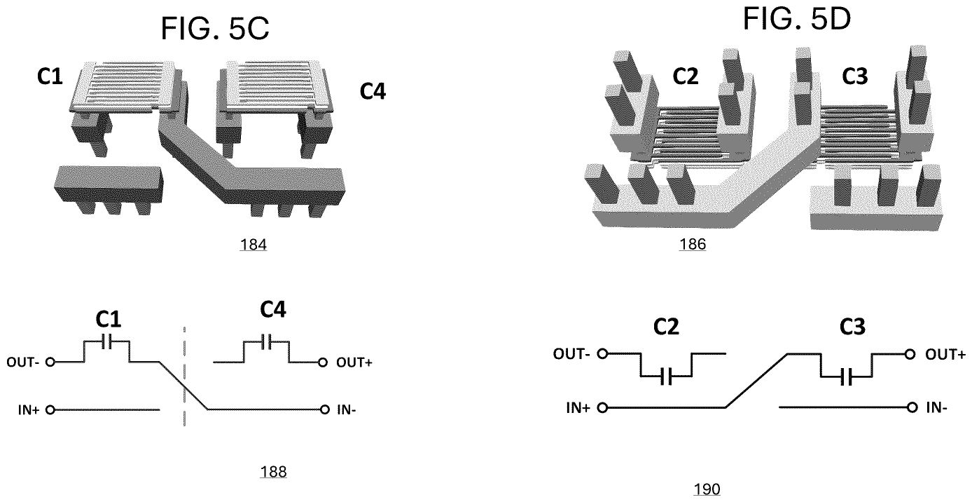

FIGS. 5A-5D describe an illustrative embodiment of a VNCAP subcircuit 106 shown in FIG. 1. FIG. 5A depicts the VNCAP subcircuit 106 and FIG. 5B depicts a perspective view of an associated three-dimensional structure 180 for implementing the VNCAP subcircuit 106. Structure 180 is implemented in two wafers, with capacitors C1 and C4 being implemented in the top wafer and capacitors C2, C3 being implemented in the bottom wafer. From a top-down perspective (i.e., a through wafer stack projection), structure 180 is left-right symmetrical about center line 182. Capacitor pair C1 and C2 (and associated components) are fabricated on a first side of center line 182 and capacitor pair C3 and C4 are fabricated on a second side of centerline 182.

FIGS. 5C and 5D show exploded views of the top and bottom wafer sections 184, 186 of structure 180 and associated circuit components 188, 190. Splitting the top/bottom wafer into two halves and bonding them together as shown will create symmetrical neutralization capacitors with a 50% area reduction. Note that if capacitors C1-C4 are implemented with the same size (W×L), the capacitance of top capacitors C1, C4 and bottom capacitors C2, C3 will be different due to the different distance from the substrate (not shown). A similar approach could be utilized to implement a symmetric MIMCAP.

Accordingly, implementing such stacked wafer structures in differential amplifier circuits and the like will achieve both a smaller footprint and high performance by providing true differential operations. Note that other structures could be similarly constructed using stacked wafers, e.g., baluns, inductors, etc. Furthermore, although described using two stacked wafers, two or more stacked wafers could be utilized. Symmetrical structures using stacked wafers may also be fabricating using any technique.

For purposes of illustration, metal oxide semiconductor field effect transistors (MOSFETs) disclosed herein may comprise P-type transistors and N-type transistors. A MOSFET refers to a transistor with a semiconductor channel region positioned laterally between a source region and a drain region and with a gate (e.g., including a gate dielectric-gate conductor stack) adjacent to the channel region. However, it should be understood that the figures and discussion thereof are not intended to be limiting. For example, alternatively, a similar circuit structure could be formed using bipolar junction transistors (BJTs) and, particularly, PNP BJTs and NPN BJTs.

It should be understood that the terminology used herein is for the purpose of describing the disclosed structures and methods and is not intended to be limiting. For example, as used herein, the singular forms “a,” “an” and “the” are intended to include the plural forms as well, unless the context clearly indicates otherwise. Additionally, as used herein, the terms “comprises,” “comprising,” “includes” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure, comprising:
a plurality of semiconductor devices and components fabricated in a wafer stack, wherein a first set of devices is implemented in a first wafer and a second set of devices is implemented in a second wafer, and wherein the devices and components have side-by-side symmetry from a through wafer stack projection about a center line.

2. The structure of claim 1, wherein the plurality of semiconductor devices includes active semiconductor devices.

3. The structure of claim 2, wherein the active semiconductor devices include a plurality of metal oxide semiconductor field effect transistors (MOSFET) devices.

4. The structure of claim 3, wherein a first pair of the plurality of MOSFET devices is formed on a first side of the center line and a second pair of the plurality of MOSFET devices is formed on a second side of the center line.

5. The structure of claim 4, wherein the first pair of the plurality of MOSFET devices is implemented in the first and second wafers, and the second pair of the plurality of MOSFET devices is implemented in the first and second wafers.

6. The structure of claim 5, wherein the first pair of the plurality of MOSFET devices is coupled together and the second pair of the plurality of MOSFET devices is coupled together.

7. The structure of claim 1, wherein the plurality of semiconductor devices includes passive semiconductor devices.

8. The structure of claim 7, wherein the passive semiconductor devices form at least one of: a transformer, a balun, an inductor, a vertical natural capacitor (VNCAP), and a metal-insulator-metal capacitor (MIMCAP).

9. The structure of claim 7, wherein the passive semiconductor devices include a plurality of capacitors, wherein a first set of capacitors is implemented in the first wafer and a second set of capacitors is implemented in the second wafer, and a first pair of capacitors is implemented on a first side of the center line in the first and second wafers, and a second pair of capacitors is implemented on a second side of the center line in the first and second wafers, and wherein the first pair of capacitors is coupled together, and the second pair of capacitors is coupled together.

10. The structure of claim 1, wherein the first wafer and the second wafer are fabricated from dissimilar materials that have different dielectric properties.

11. A circuit, comprising:
a plurality of subcircuits, wherein each subcircuit is implemented with a structure that includes:
a plurality of devices and components fabricated in stacked wafers, wherein a first set of devices is implemented in a first wafer and a second set of devices is implemented in a second wafer, and wherein the devices and components have side-by-side symmetry from a through wafer stack projection relative to a center line.

12. The circuit of claim 11, wherein the plurality of subcircuits form a differential amplifier.

13. The circuit of claim 11, wherein for each subcircuit, a first subset of the plurality of devices and components is formed on a first side of the center line and a second subset of the plurality of devices and components is formed on a second side of the center line.

14. The circuit of claim 13, wherein for a first subcircuit, the plurality of devices comprises metal-oxide semiconductor field-effect transistor (MOSFET) devices, and wherein a first pair of MOSFETS is implemented on the first side in the first and second wafers, and a second pair of MOSFETS is implemented on the second side in the first and second wafers.

15. The circuit of claim 14, wherein the first pair of MOSFETS is coupled together and the second pair of MOSFETS is coupled together.

16. The circuit of claim 14, wherein for a second subcircuit, the plurality of devices comprises inductor devices that form a transformer, wherein a first pair of inductors is implemented on the first side in the first and second wafers, and a second pair of inductors is implemented on the second side in the first and second wafers, and wherein one of the inductors of the first pair of inductors implemented in the first wafer is coupled to one of the inductors of the second pair of inductors implemented in the second wafer.

17. The circuit of claim 13, wherein for at least one of the subcircuits, the plurality of devices comprises capacitors.

18. The circuit of claim 17, wherein a first pair of capacitors is implemented on the first side in the first and second wafers, and a second pair of capacitors is implemented on the second side in the first and second wafers, wherein the first pair of capacitors is coupled together, and the second pair of capacitors is coupled together.

19. The circuit of claim 18, wherein the first pair and the second pair of capacitors form one of a vertical natural capacitor (VNCAP) or a metal-insulator-metal capacitor (MIMCAP).

20. The circuit of claim 11, wherein the first wafer and the second wafer are fabricated from dissimilar materials that have different dielectric properties.
